(19) United States
(12) Patent Application Publication
(10) Pub. No.: US 2008/0157220 A1
(43) Pub. Date: Jul. 3, 2008

(54) Semiconductor Device and Manufacturing Method Thereof

(76) Inventor: SUNG JOONG JOO, Incheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/930,385

(22) Filed: Oct. 31, 2007

(30) Foreign Application Priority Data
Dec. 27, 2006 (KR) 10-2006-0135568

(51) Int. Cl. H01L 29/78; H01L 21/3205

(52) U.S. Cl. 257/384; 438/586; 257/E29.255; 257/E21.294

(57) ABSTRACT

A semiconductor device and a manufacturing method thereof are provided. A gate electrode and source/drain areas are disposed on a semiconductor substrate, and an interlayer dielectric layer is on the gate electrode, the source/drain areas, and the semiconductor substrate. Metal silicide layers are disposed in the gate electrode and the source/drain areas at regions exposed by contact holes.

### CROSS-REFERENCE TO RELATED APPLICATION

The present application claims the benefit under 35 U.S.C. § 119 of Korean Patent Application No. 10-2006-0135568, filed Dec. 27, 2006, which is hereby incorporated by reference in its entirety.

### BACKGROUND

As semiconductor devices become highly integrated, the dimensions of various patterns become smaller, such as the width of a gate line, the junction depth of a source/drain area, and the sectional area of a contact.

Micro-sized patterns generally cause the resistance of semiconductor devices to increase.

As the resistance of a semiconductor device increases, the operation speed of the device typically decreases, and power consumption increases.

Thus, there exists a need in the art for an improved semiconductor device and fabricating method thereof.

### BRIEF SUMMARY

Embodiments of the present invention provide a semiconductor device and a manufacturing method thereof. According to an embodiment, cobalt (Co) silicide layers can be partially formed in gate and source/drain areas to inhibit leakage current and increase the reliability of the device.

In an embodiment, a method of manufacturing a semiconductor device can include forming a gate electrode and source/drain areas on a semiconductor substrate, and then forming an interlayer dielectric layer on the semiconductor substrate. Contact holes can be formed in the interlayer dielectric layer to expose the gate electrode and the source/drain areas, and metal silicide layers can be formed in the gate electrode and the source/drain areas exposed by the contact holes.

A semiconductor device according to an embodiment of the present invention can include: a gate electrode on a semiconductor substrate; source/drain areas on the semiconductor substrate; an interlayer dielectric layer on the semiconductor substrate; contacts electrically connecting the gate electrode and the source/drain areas to a metal layer; and silicide layers in the gate electrode and the source/drain areas.

### BRIEF DESCRIPTION OF THE DRAWINGS

FIGS. 1 to 6 are cross-sectional views illustrating a manufacturing method of a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

FIG. 6 is a cross-sectional view of a semiconductor device according to an embodiment of the present invention.

Referring to FIG. 6, isolation layers 20 can be formed on a semiconductor substrate 10 to define an active area.

A gate insulating layer 30 can be on the active area, and a gate electrode 40 can be on the gate insulating layer 30.

Spacers 50 can be on sidewalls of the gate electrode 40, and source/drain areas 60 can be on the semiconductor substrate 10 at sides of the gate electrode 40. The source/drain areas 60 can be formed through impurity ion implantation.

Cobalt (Co) silicide layers 130 can be formed in the gate electrode 40 and the source/drain areas 60, electrically connected to a metal layer 160 to help reduce resistance.

In an embodiment, the Co silicide layers 130 can be formed only at portions of the gate electrode 40 and the source/drain areas 60, electrically connected to the metal layer 160.

Accordingly, the Co silicide layers 130 in the source/drain areas 60 can be spaced apart from the Co silicide layer 130 in the gate electrode 40.

An interlayer dielectric layer 70 can be on the semiconductor substrate 10 including the gate electrode 40 and the source/drain areas 60. The interlayer dielectric layer 70 can have any suitable structure known in the art, for example, a structure in which boron phosphor silicate glass (BPSG) and dual tetraethyl orthosilicate (D-TEOS) are stacked together.

Contact holes 80 (see FIG. 2) passing through the interlayer dielectric layer 70 can be present.

A titanium (Ti) layer 140 and a titanium nitride (TiN) layer 150 can be on the interlayer dielectric layer 70 and in the contact holes 80.

The metal layer 160 can be a metallic material on the interlayer dielectric layer 70 and in the contact holes 80. For example, the metallic material can be tungsten (W). The metal layer 160 can be electrically connected to the gate electrode 40 and the source/drain areas 60.

In an embodiment, the Co silicide layers 130 can be at the portions of the gate electrode 40 and the source/drain areas 60 which are in contact with the via hole for the metal layer 160. Accordingly, a leakage current from the source/drain areas 60 and the gate electrode 40 can be inhibited by the Co silicide layers 130.

Hereinafter, a manufacturing method of a semiconductor device according to an embodiment of the present invention will be described.

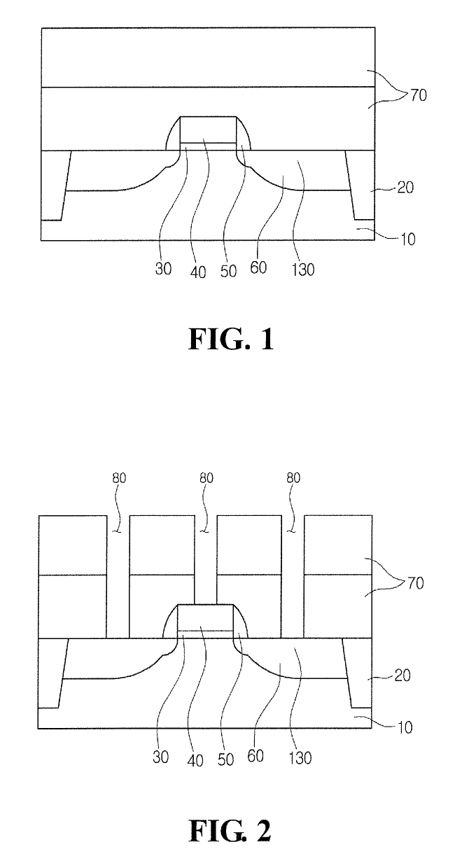

Referring to FIG. 1, isolation layers 20 can be formed on a semiconductor substrate 10 to define an active area. The isolation layers 20 can be, for example, STI (Shallow Trench Isolation) areas.

The semiconductor substrate 10 can be any appropriate substrate known in the art, for example, a single crystalline silicon substrate. The semiconductor substrate 10 can be doped with P-type or N-type impurities.

An oxide layer and polysilicon can be stacked on the semiconductor substrate 10 through a transistor forming process known in the art. Then, a gate insulating layer 30 and a gate electrode 40 can be sequentially formed through an etching process known in the art.

The gate electrode 40 can be any appropriate material known in the art, for example, polysilicon, metal, or any combination thereof. In embodiments in which the semiconductor device will be highly integrated, the gate electrode 40 can be a metal gate.

A Lightly-Doped Drain (LDD) area can be formed in the semiconductor substrate 10 through low-density dopant implantation using the gate electrode 40 as a mask. In an embodiment, the low-density dopant implantation can include implanting N-type impurities. In a further embodiment, the low-density dopant implantation can include implanting P-type impurities.

An insulating layer can be deposited and etched on the semiconductor substrate 10 and the gate electrode 40 to form spacers 50 coming into contact with sidewalls of the gate electrode 40.

Source/drain areas 60 connected to the LDD area can be formed through high-density dopant implantation using the gate electrode 40 and the spacers 50 as a mask. A heat treatment for activation of dopants implanted into the source/drain areas 60 can be performed. In an embodiment, the high-density dopant implantation can include implanting N-type impurities. In a further embodiment, the high-density dopant implantation can include implanting P-type impurities.

An interlayer dielectric layer 70 can be formed on the semiconductor substrate 10 including the gate electrode 40 and the source/drain areas 60. The interlayer dielectric layer 70 can be formed to have any appropriate structure known in the art, for example, a structure in which BPSG and D-TEOS are stacked together.

Referring to FIG. 2, a photoresist pattern (not shown) can be formed on the interlayer dielectric layer 70. The upper surfaces of the gate electrode 40 and the source/drain areas 60 can be exposed through a photolithography and etching process to form contact holes 80 in the interlayer dielectric layer 70.

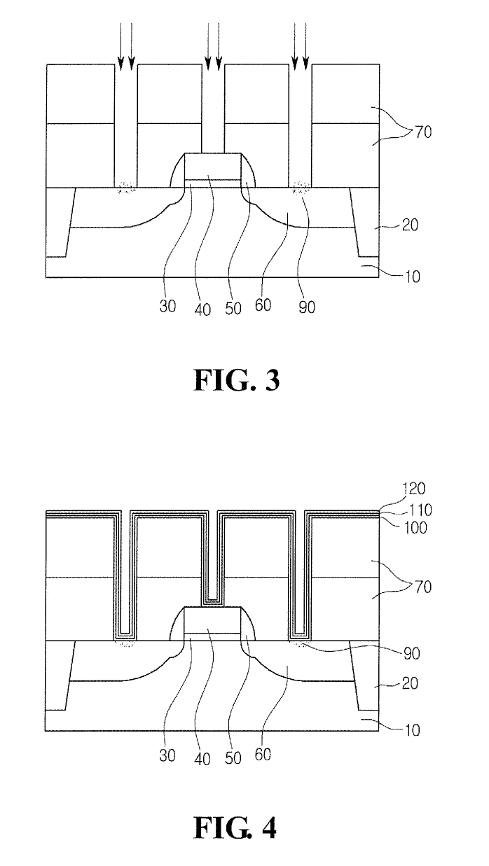

Referring to FIG. 3, ions 90 can be implanted into the interlayer dielectric layer 70 and into the gate electrode 40 and the source/drain areas 60 through the contact holes 80. The ions can be implanted through a pre-amorphization implantation (PAI) process. In an embodiment, the ions 90 can be germanium (Ge) ions.

During a process of forming a Co silicide layer 130 on a polycrystalline silicon layer, Co atoms may be diffused along a grain boundary of the polycrystalline silicon layer, which could lead to agglomeration in the Co silicide layer 130. For this reason, it can often be difficult to uniformly produce a Co silicide layer 130. Additionally, the resistance of a metal layer in a contact hole 80 may be increased. In order to solve these problems, a process for converting the polycrystalline silicon layer into an amorphous silicon layer, such as a PAI process, can be performed.

The surfaces of the gate electrode 40 and the source/drain areas 60, which can be silicon layers, can be converted into amorphous silicon layers by implanting the ions 90 into the gate electrode 40 and the source/drain areas 60. In an embodiment, ions 90 are Ge ions and are implanted through a PAI process.

In an embodiment, a PAI process can be performed in which Ge ions are implanted at a dosage of about 5.0×10¹¹ atoms/cm² to about 5.0×10¹³ atoms/cm² at an energy of about 10 keV to about 20 keV.

Referring to FIG. 4, a first metal layer for a silicide forming process can be deposited on the interlayer dielectric layer 70.

In an embodiment, the first metal layer can include three sequentially stacked layers such as a Co layer 100, a Ti layer 110 and a TiN layer 120. For example, the Co layer 100 can be deposited with a thickness of about 170 Å to about 185 Å, the Ti layer 110 can be deposited with a thickness of about 190 Å to about 210 Å, and the TiN layer 120 can be deposited with a thickness of about 210 Å to about 230 Å. In one embodiment, the thickness of the Co layer 100 can be about 180 Å, the thickness of the Ti layer 110 can be about 200 Å, and the thickness of the TiN 120 can be about 220 Å.

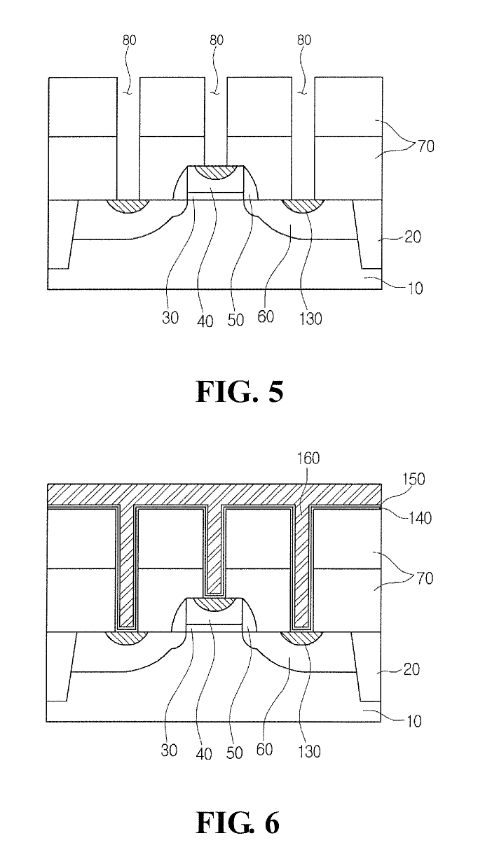

Referring to FIG. 5, Co silicide layers 130 can be formed in the gate electrode 40 and the source/drain areas 60. The Co silicide layers 130 can be formed by, for example, performing primary and secondary heat treatment processes.

The primary heat treatment process can be a heat treatment process performed after the first metal layer is formed on the interlayer dielectric layer 70. In an embodiment, the primary heat treatment process can be rapid thermal annealing (RTA) performed at a temperature of about 484° C. to about 540° C. for a period of time of about 50 seconds to about 70 seconds. In a further embodiment, RTA can be performed for about 60 seconds. The Co layer 100 can be diffused and reacted with the gate electrode 40 and the source/drain areas 60 through the primary heat treatment process such that the Co layer 100 is silicidated.

During the primary heat treatment process, the gate electrode 40 and the source/drain areas 60 can be changed into silicide layers due to the reaction with the Co layer 100. Portions of the first metal layer that remain unreacted can be removed through an etching process.

In an embodiment, the secondary heat treatment process can be RTA performed at a temperature of about 800° C. to about 850° C. for a period of time of about 20 seconds to about 40 seconds. In a further embodiment, RTA can be performed for about 30 seconds. Accordingly, Co silicide layers 130 can be formed in the gate electrode 40 and the source/drain areas 60.

The Co silicide layers 130 can be formed at bottom portions of the contact holes 80 on the gate electrode 40 and the source/drain areas 60, electrically connected to the metal layer 160. Accordingly, the Co silicide layers 130 on the source/drain areas can be spaced apart from the Co silicide layer 130 on the gate electrode 40 to inhibit leakage current.

Referring to FIG. 6, a second metal layer can be deposited on the interlayer dielectric layer 70 and in the contact holes 80 to form a metal layer 160. The metal layer 160 can include any suitable metal known in the art, such as W.

The second metal layer can include a Ti layer 140, a TiN layer 150, or both. In an embodiment, the Ti layer 140 can be deposited with a thickness of about 250 Å to about 350 Å, and the TiN layer 150 can be deposited with a thickness of about 10 Å to about 100 Å.

Then, the metal layer 160 can be planarized to form contacts. Any appropriate planarization process known in the art can be used, for example, chemical mechanical polishing (CMP).

In embodiments of the present invention, silicide layer areas can be formed at bottom portions of contact holes passing through an interlayer dielectric layer. Accordingly, leakage current that may be produced between a gate electrode and source/drain areas can be inhibited. This leads to increased reliability of the semiconductor device.

Moreover, embodiments allow for high integration of semiconductor devices.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, comprising:
forming a gate electrode on a semiconductor substrate; forming source/drain areas on the semiconductor substrate;
forming an interlayer dielectric layer on the semiconductor substrate and the gate electrode;
forming contact holes in the interlayer dielectric layer exposing the gate electrode and the source/drain areas; and
forming metal silicide layers in the gate electrode and the source/drain areas exposed by the contact holes.

2. The method according to claim 1, further comprising:
implanting ions into the interlayer dielectric layer and the gate electrode and the source/drain areas after forming the contact holes in the interlayer dielectric layer; and
forming a first metal layer on the interlayer dielectric layer the gate electrode, and the source/drain areas after forming the contact holes in the interlayer dielectric layer, wherein the first metal layer is used informing the metal silicide layers.

3. The method according to claim 2, wherein forming the metal silicide layers comprises:
performing a primary heat treatment process to react the first metal layer with the gate electrode and the source/drain areas;
removing unreacted portions of the first metal layer; and
performing a secondary heat treatment process to form the metal silicide layers.

4. The method according to claim 3, wherein the primary heat treatment process is performed at a temperature of about 484° C. to about 540° C. for a period of time of about 50 seconds to about 70 seconds.

5. The method according to claim 3, wherein the secondary heat treatment process is performed at a temperature of about 800° C. to about 850° C. for a period of time of about 20 seconds to about 40 seconds.

6. The method according to claim 2, wherein the ions are germanium (Ge) ions, and wherein implanting the ions comprises performing a pre-amorphization implantation (PAI) process.

7. The method according to claim 6, wherein the PAI process comprises implanting Ge ions at a dosage of about 5.0×10¹¹ atoms/cm² to about 5.0×10¹³ atoms/cm² at an energy of about 10 keV to about 20 keV.

8. The method according to claim 2, wherein the first metal layer comprises a cobalt (Co) layer, a titanium (Ti) layer, and a titanium nitride (TiN) layer.

9. The method according to claim 8, wherein a thickness of the Co layer is about 170 Å to about 185 Å, and wherein a thickness of the Ti layer is about 190 Å to about 210 Å, and wherein a thickness of the TiN layer is about 210 Å to about 230 Å.

10. The method according to claim 1, further comprising forming a second metal layer on the interlayer dielectric layer and in the contact holes after forming the metal silicide layers.

11. The method according to claim 10, wherein the second metal layer comprises tungsten (W).

12. The method according to claim 10, wherein the second metal layer comprises a Ti layer and a TiN layer.

13. The method according to claim 12, wherein a thickness of the Ti layer is about 250 Å to about 350 Å, and wherein a thickness of the TiN layer is about 10 Å to about 100 Å.

14. The method according to claim 1, wherein the metal silicide layers comprise a Co silicide.

15. A semiconductor device, comprising:
a gate electrode on a semiconductor substrate;
source/drain areas on the semiconductor substrate at sides of the gate electrode;
an interlayer dielectric layer on the semiconductor substrate including the gate electrode;
contacts passing through the interlayer dielectric layer to the gate electrode and the source/drain areas, respectively; and
metal silicide layers in the gate electrode and the source/drain areas only at portions corresponding to the contacts.

16. The semiconductor device according to claim 15, wherein each metal silicide layer is spaced apart from every other metal silicide layer.

17. The semiconductor device according to claim 15, wherein each metal silicide layer comprises a Co silicide layer.

18. The semiconductor device according to claim 15, wherein the contacts comprise W.

19. The semiconductor device according to claim 15, wherein the contacts comprise a Ti layer and a TiN layer.

20. The semiconductor device according to claim 19, wherein a thickness of the Ti layer is about 250 Å to about 350 Å, and wherein a thickness of the TiN layer is about 10 Å to about 100 Å.
